(19) United States
(12) Patent Application Publication
(10) Pub. No.: US 2025/0327164 A1
(43) Pub. Date: Oct. 23, 2025

(54) DEPOSITION MASK AND METHOD OF MANUFACTURING THE SAME

(71) Applicant: Samsung Display Co., LTD., Yongin-si (KR)

(72) Inventors: Duck Jung LEE, Yongin-si (KR); Sung Woon KIM, Yongin-si (KR)

(21) Appl. No.: 18/980,399

(22) Filed: Dec. 13, 2024

(30) Foreign Application Priority Data
Apr. 23, 2024 (KR) 10-2024-0053862

(51) Int. Cl. C23C 14/04; H10K 71/16

(52) U.S. Cl. CPC C23C 14/042; H10K 71/166

(57) ABSTRACT

A deposition mask includes: a substrate; a first inorganic film on the substrate; and a mask membrane on the first inorganic film and including a second inorganic film and a third inorganic film. A cross-sectional structure of the mask membrane has a reverse tapered shape formed by a second inorganic film pattern obtained by patterning the second inorganic film and the third inorganic film covering a top surface and a side surface of the second inorganic film pattern.

### CROSS-REFERENCE TO RELATED APPLICATION

The present application claims priority to and the benefit of Korean Patent Application No. 10-2024-0053862, filed on Apr. 23, 2024, in the Korean Intellectual Property Office, the entire disclosure of which is incorporated herein by reference.

### BACKGROUND

### 1. Field

Aspects of embodiments of the present disclosure relate to a deposition mask and a method of manufacturing the same.

### 2. Description of the Related Art

Wearable devices in which a focus is formed at a distance close to a user's eyes have been developed in the form of glasses or a helmet. For example, the wearable device may be a head mounted display (HMD) device or AR glasses. The wearable device provides an augmented reality (hereinafter, referred to as “AR”) screen or a virtual reality (hereinafter, referred to as “VR”) screen to a user.

The wearable devices, such as the HMD device or the AR glasses, often utilize a display specification of at least 2000 PPI (pixels per inch) so that a user may use it for a long time without dizziness or discomfort. To this end, organic light-emitting diode on silicon (OLEDoS) technology, which is a high-resolution, small organic light-emitting display device, is emerging. The organic light-emitting diode on silicon (OLEDoS) is technology for disposing an organic light-emitting diode (OLED) on a semiconductor wafer substrate on which a complementary metal oxide semiconductor (CMOS) is disposed.

### SUMMARY

Embodiments of the present disclosure provide a deposition mask for manufacturing a high-resolution, organic light-emitting display device and a deposition mask and a method of manufacturing the same with improved reliability by improving pixel position accuracy (PPA).

Embodiments of the present disclosure also provide a deposition mask and a method of manufacturing the same capable of reducing shadow defects and deposition material buildup on the mask.

According to an embodiment of the present disclosure, a deposition mask includes a substrate; a first inorganic film on the substrate; and a mask membrane on the first inorganic film and including a second inorganic film and a third inorganic film. A cross-sectional structure of the mask membrane has a reverse tapered shape formed by a second inorganic film pattern obtained by patterning the second inorganic film and the third inorganic film covering a top surface and a side surface of the second inorganic film pattern.

In an embodiment, a thickness of the third inorganic film covering the side surface of the second inorganic film pattern in the mask membrane increases as it approaches the top surface of the second inorganic film pattern.

According to another embodiment of the present disclosure, a method of manufacturing a deposition mask includes depositing a first inorganic film and a second inorganic film on a substrate, forming a plurality of second inorganic film patterns corresponding to a cell region of the substrate by patterning the second inorganic film, forming a cell opening exposing the second inorganic film pattern by etching the substrate and the first inorganic film from a lower direction of the substrate, and depositing a third inorganic film covering a top surface and a side surface of the second inorganic film pattern. In the depositing of the third inorganic film, the second inorganic film pattern and the third inorganic film deposited on a surface of the second inorganic film pattern form a mask membrane having a reverse tapered shape.

In an embodiment, the substrate may include silicon (Si).

In an embodiment, the first inorganic film may include silicon oxide (SiOx).

In an embodiment, the second inorganic film may include silicon nitride (SiNx).

In an embodiment, the third inorganic film may be deposited by using a chemical vapor deposition (CVD) method.

In an embodiment, the third inorganic film may be deposited by using an atomic layer deposition (ALD) method.

In an embodiment, a material of the third inorganic film may be the same as a material of the first inorganic film or a material of the second inorganic film.

In an embodiment, a taper angle of the mask membrane may be in a range of 70 degrees to 90 degrees.

In an embodiment, a deposition thickness of the third inorganic film on the side surface of the second inorganic film pattern may be less than 0.4 μm, and a deposition thickness of the third inorganic film on the top surface of the second inorganic film pattern may be less than 1 μm.

According to another embodiment of the present disclosure, a method of manufacturing a deposition mask includes depositing a first inorganic film and a second inorganic film on a substrate, forming a plurality of second inorganic film patterns corresponding to a cell region of the substrate by patterning the second inorganic film, depositing a third inorganic film covering a top surface and a side surface of the second inorganic film pattern, removing the third inorganic film deposited on the top surface of the second inorganic film pattern by polishing a top surface of the substrate on which the third inorganic film is deposited, and forming a cell opening exposing the second inorganic film pattern by etching the substrate and the first inorganic film from a lower direction of the substrate. In the depositing of the third inorganic film, the second inorganic film pattern and the third inorganic film deposited on a surface of the second inorganic film pattern form a mask membrane having a reverse tapered shape.

In an embodiment, the substrate may include silicon (Si).

In an embodiment, the first inorganic film may include silicon oxide (SiOx).

In an embodiment, the second inorganic film may include silicon nitride (SiNx).

In an embodiment, the third inorganic film may be deposited by using a chemical vapor deposition (CVD) method.

In an embodiment, the third inorganic film may be deposited by using an atomic layer deposition (ALD) method.

In an embodiment, a material of the third inorganic film may be the same as a material of the first inorganic film or a material of the second inorganic film.

In an embodiment, a taper angle of the mask membrane may be in a range of 70 degrees to 90 degrees.

In an embodiment, a deposition thickness of the third inorganic film on the side surface of the second inorganic film pattern may be less than 0.4 μm, and a deposition thickness of the third inorganic film on the top surface of the second inorganic film pattern may be less than 1 μm.

According to another embodiment of the present disclosure, an electronic device includes a display device manufactured using a deposition mask and configured to provide an image, a processor configured to provide an image data signal to the display device, a memory configured to store a data information for operation, and a power module configured to generate power. The deposition mask includes a substrate, a first inorganic film on the substrate, and a mask membrane on the first inorganic film and including a second inorganic film and a third inorganic film. A cross-sectional structure of the mask membrane has a reverse tapered shape formed by a second inorganic film pattern obtained by patterning the second inorganic film and the third inorganic film covering a top surface and a side surface of the second inorganic film pattern.

In accordance with the deposition mask and the method of manufacturing the same according to embodiments of the present disclosure, reliability is improved by improving pixel position accuracy (PPA).

In addition, shadow defects and deposition material buildup on the mask is reduced.

The aspects and features of the present disclosure are not limited to the aforementioned aspects and features, and various other aspects and features are included in the present specification.

### BRIEF DESCRIPTION OF THE DRAWINGS

The above and other aspects and features of the present disclosure will become more apparent by describing, in detail, embodiments thereof with reference to the attached drawings, in which:

FIG. 1 is an exploded perspective view of a display device according to one embodiment;

FIG. 2 is a block diagram of a display device according to one embodiment;

FIG. 3 is an equivalent circuit diagram of a first sub-pixel according to one embodiment;

FIG. 4 is a layout diagram of a display panel according to one embodiment;

FIGS. 5 and 6 are layout diagrams of the display area shown in FIG. 4 according to various embodiments;

FIG. 7 is a cross-sectional view of the display panel shown in FIG. 5 taken along the line I1-I1′ in FIG. 5;

FIG. 8 is a perspective view of a head mounted display according to one embodiment;

FIG. 9 is an exploded perspective view of the head mounted display shown in FIG. 8;

FIG. 10 is a perspective view of a head mounted display according to one embodiment;

FIG. 11 is a perspective view of a mask according to one embodiment;

FIG. 12 is a schematic plan view of a mask according to one embodiment;

FIGS. 13 to 16 are cross-sectional views showing steps of a method of manufacturing a mask according to one embodiment;

FIGS. 17 to 21 are cross-sectional views showing steps of a method of manufacturing a mask according to another embodiment;

FIG. 22 is a cross-sectional view of a mask membrane according to one embodiment; and

FIG. 23 is a configuration diagram schematically illustrating deposition equipment according to one embodiment.

FIG. 24 is a block diagram of an electronic device according to one embodiment of the present disclosure.

FIG. 25 is a schematic diagram of an electronic device according to various embodiments of the present disclosure.

### DETAILED DESCRIPTION

The present disclosure will now be described more fully hereinafter with reference to the accompanying drawings, in which embodiments of the present disclosure are shown. The present disclosure may, however, be embodied in different forms and should not be construed as limited to the embodiments set forth herein. Rather, these embodiments are provided so that this disclosure will be thorough and complete, and will filly convey the scope of the invention to those skilled in the art.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112 (a) and 35 U.S.C. § 132 (a).

Hereinafter, embodiments of the present disclosure will be described with reference to the accompanying drawings.

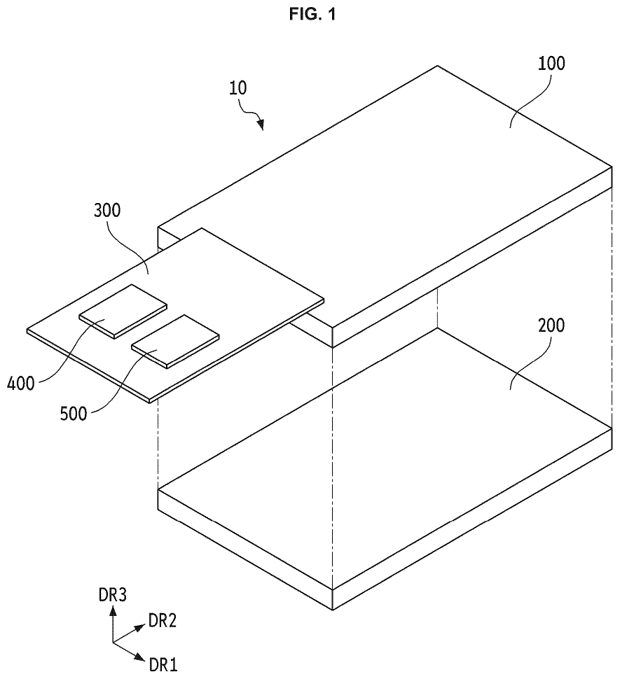

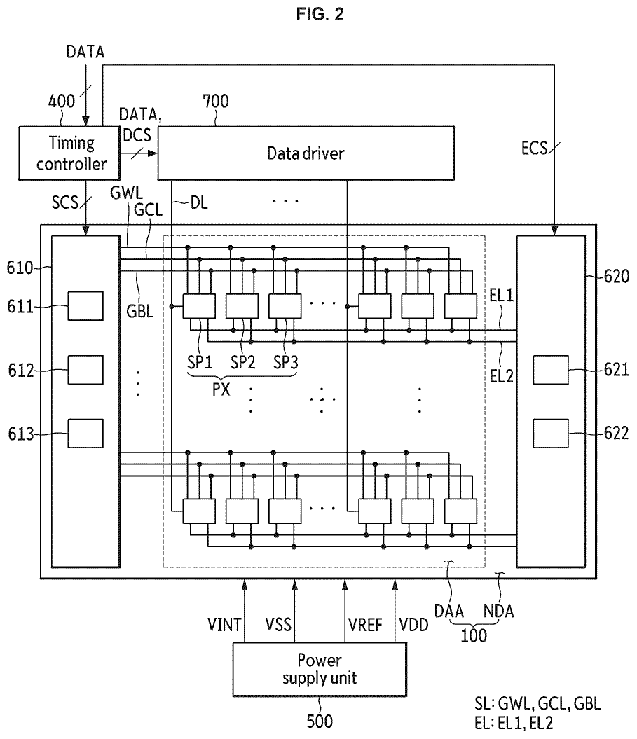

FIG. 1 is an exploded perspective view of a display device according to one embodiment. FIG. 2 is a block diagram of a display device according to one embodiment.

Referring to FIGS. 1 and 2, a display device 10, according to one embodiment, is a device configured to display a moving image and/or a still image. The display device 10, according to one embodiment, may be applied to portable electronic devices, such as a mobile phone, a smartphone, a tablet personal computer, a mobile communication terminal, an electronic organizer, an electronic book, a portable multimedia player (PMP), a navigation system, an ultra-mobile PC (UMPC), or the like. For example, the display device 10, according to one embodiment, may be applied as a display unit of a television, a laptop, a monitor, a billboard, or an Internet-of-Things (IoT) terminal or device. In another embodiment, the display device 10 may be applied to a smart watch, a watch phone, a head mounted display (HMD) for implementing virtual reality and/or augmented reality, and the like.

The display device 10, according to one embodiment, includes a display panel 100, a heat dissipation layer 200, a circuit board 300, a timing controller 400, and a power supply circuit 500.

The display panel 100 may have a planar shape similar to a quadrilateral shape. For example, the display panel 100 may have a planar shape similar to a quadrilateral shape, having a short side of a first direction DR1 and a long side of a second direction DR2 crossing (e.g., intersecting) the first direction DR1. In the display panel 100, a corner at where a short side in the first direction DR1 and a long side in the second direction DR2 meet may be right-angled or rounded with a curvature (e.g., a predetermined curvature). The planar shape of the display panel 100 is not limited to a quadrilateral shape and may be a shape similar to another polygonal shape, a circular shape, or an elliptical shape. The planar shape of the display device 10 may conform to the planar shape of the display panel 100, but the present disclosure is not limited thereto.

The display panel 100 has a display area DAA at where an image is displayed and a non-display area NDA where an image is not displayed, as shown in FIG. 2.

The display area DAA includes a plurality of pixels PX, a plurality of scan lines SL, a plurality of emission control lines EL, and a plurality of data lines DL.

The plurality of pixels PX may be arranged in a matrix form in the first direction DR1 and the second direction DR2. The plurality of scan lines SL and the plurality of emission control lines EL may extend in the first direction DR1, while being arranged in the second direction DR2. The plurality of data lines DL may extend in the second direction DR2 while being arranged in (e.g., adjacent to each other in) the first direction DR1.

The plurality of scan lines SL include a plurality of write scan lines GWL, a plurality of control scan lines GCL, and a plurality of bias scan lines GBL. The plurality of emission control lines EL include a plurality of first emission control lines EL1 and a plurality of second emission control lines EL2.

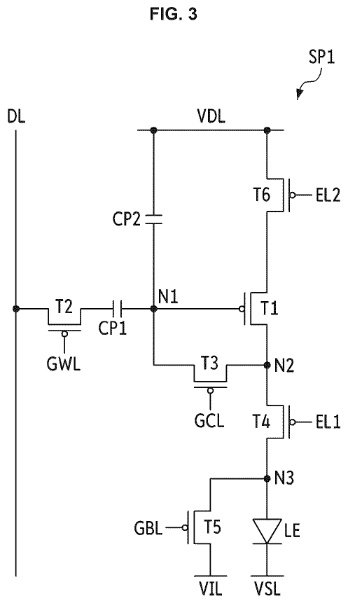

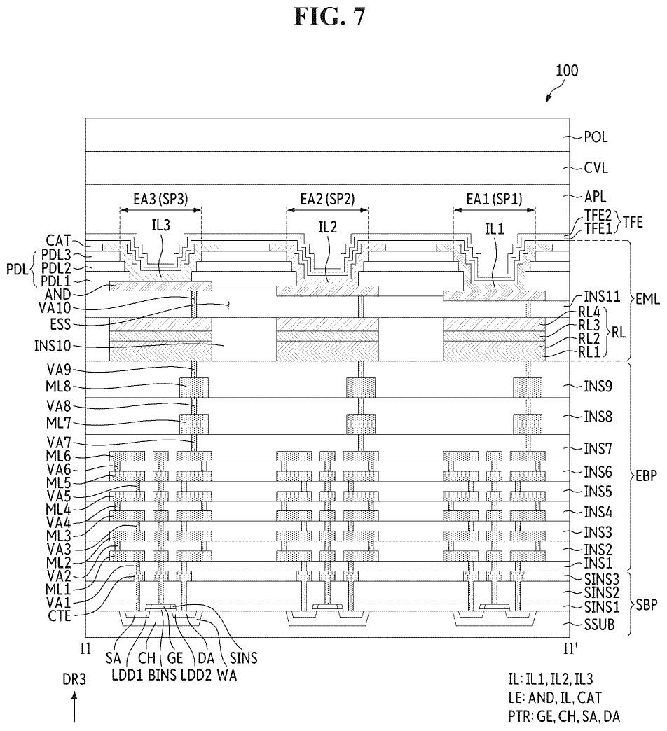

The plurality of pixels PX include a plurality of sub-pixels SP1, SP2, and SP3. The plurality of sub-pixels SP1, SP2, and SP3 may include a plurality of pixel transistors as shown in FIG. 3, and the plurality of pixel transistors may be formed by a semiconductor process and disposed on a semiconductor substrate SSUB (see, e.g., FIG. 7). For example, the plurality of pixel transistors of a data driver 700 may be formed of complementary metal oxide semiconductor (CMOS).

Each of the plurality of sub-pixels SP1, SP2, and SP3 may be connected to any one write scan line GWL from among the plurality of write scan lines GWL, any one control scan line GCL from among the plurality of control scan lines GCL, any one bias scan line GBL from among the plurality of bias scan lines GBL, any one first emission control line EL1 from among the plurality of first emission control lines EL1, any one second emission control line EL2 from among the plurality of second emission control lines EL2, and any one data line DL from among the plurality of data lines DL. Each of the plurality of sub-pixels SP1, SP2, and SP3 may receive a data voltage of the data line DL in response to a write scan signal of the write scan line GWL and may emit light from the light-emitting element according to the data voltage.

The non-display area NDA includes a scan driver 610, an emission driver 620, and a data driver 700.

The scan driver 610 includes a plurality of scan transistors, and the emission driver 620 includes a plurality of light-emitting transistors. The plurality of scan transistors and the plurality of light-emitting transistors may be formed on the semiconductor substrate SSUB (see, e.g., FIG. 7) through a semiconductor process. For example, the plurality of scan transistors and the plurality of light-emitting transistors may be formed of CMOS. Although the embodiment shown in FIG. 2 has the scan driver 610 disposed on the left side of the display area DAA and the emission driver 620 disposed on the right side of the display area DAA, the present disclosure is not limited thereto. For example, the scan driver 610 and the emission driver 620 may both be disposed on the left side or on the right side of the display area DAA.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing controller 400. The write scan signal output unit 611 may generate write scan signals according to the scan timing control signal SCS of the timing controller 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to the bias scan lines GBL.

The emission driver 620 includes a first emission control driver 621 and a second emission control driver 622. Each of the first emission control driver 621 and the second emission control driver 622 may receive an emission timing control signal ECS from the timing controller 400. The first emission control driver 621 may generate first emission control signals according to the emission timing control signal ECS and sequentially output them to the first emission control lines EL1. The second emission control driver 622 may generate second emission control signals according to the emission timing control signal ECS and sequentially output them to the second emission control lines EL2.

The data driver 700 may include a plurality of data transistors, and the plurality of data transistors may be formed on the semiconductor substrate SSUB (see, e.g., FIG. 7) through a semiconductor process. For example, the plurality of data transistors may be formed of CMOS.

The data driver 700 may receive digital video data DATA and a data timing control signal DCS from the timing controller 400. The data driver 700 converts the digital video data DATA into analog data voltages according to the data timing control signal DCS and outputs the analog data voltages to the data lines DL. In such an embodiment, the sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is the thickness direction of the display panel 100. The heat dissipation layer 200 may be disposed on one surface of the display panel 100, for example, on the rear surface thereof. The heat dissipation layer 200 dissipates heat generated in the display panel 100. The heat dissipation layer 200 may include a metal layer, such as graphite, silver (Ag), copper (Cu), or aluminum (Al) having high thermal conductivity.

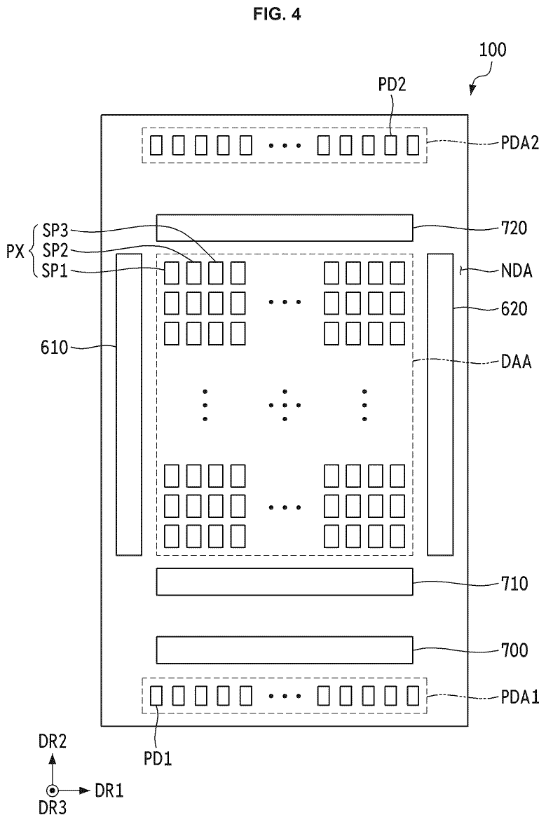

The circuit board 300 may be electrically connected to a plurality of first pads PD1 (see, e.g., FIG. 4) of a first pad portion PDA1 of the display panel 100 by using a conductive adhesive member, such as an anisotropic conductive film. The circuit board 300 may be a flexible printed circuit board including a flexible material or a flexible film. Although the circuit board 300 is illustrated in FIG. 1 as being unfolded (e.g., in an unfolded state), the circuit board 300 may be bent. When bent, one end of the circuit board 300 may be disposed on (or under) the rear surface of the display panel 100 and/or the rear surface of the heat dissipation layer 200. One end of the circuit board 300 may be an opposite end of the other end of the circuit board 300 connected to the plurality of first pads PD1 (see, e.g., FIG. 4) of the first pad portion PDA1 of the display panel 100 by using a conductive adhesive member.

The timing controller 400 may receive digital video data DATA and timing signals inputted from the outside. The timing controller 400 may generate the scan timing control signal SCS, the emission timing control signal ECS, and the data timing control signal DCS for controlling the display panel 100 in response to the timing signals. The timing controller 400 may output the scan timing control signal SCS to the scan driver 610 and may output the emission timing control signal ECS to the emission driver 620. The timing controller 400 may output the digital video data DATA and the data timing control signal DCS to the data driver 700.

The power supply circuit 500 may generate a plurality of panel driving voltages according to a power voltage from the outside. For example, the power supply circuit 500 may generate a first driving voltage VSS, a second driving voltage VDD, and a third driving voltage VINT and may supply them to the display panel 100. The first driving voltage VSS, the second driving voltage VDD, and the third driving voltage VINT will be described later with reference to FIG. 3.

Each of the timing controller 400 and the power supply circuit 500 may be formed as an integrated circuit (IC) and attached to one surface of the circuit board 300. In such an embodiment, the scan timing control signal SCS, the emission timing control signal ECS, the digital video data DATA, and the data timing control signal DCS of the timing controller 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

In another embodiment, similar to the scan driver 610, the emission driver 620, and the data driver 700, each of the timing controller 400 and the power supply circuit 500 may be disposed in the non-display area NDA of the display panel 100. In such an embodiment, the timing controller 400 may include a plurality of timing transistors, and each power supply circuit 500 may include a plurality of power transistors. The plurality of timing transistors and the plurality of power transistors may be formed on the semiconductor substrate SSUB (see, e.g., FIG. 7) through a semiconductor process. For example, the plurality of timing transistors and the plurality of power transistors may be formed of CMOS. Each of the timing controller 400 and the power supply circuit 500 may be disposed between the data driver 700 and the first pad portion PDA1 (see, e.g., FIG. 4).

FIG. 3 is an equivalent circuit diagram of a first sub-pixel according to one embodiment.

Referring to FIG. 3, the first sub-pixel SP1 may be connected to the write scan line GWL, the control scan line GCL, the bias scan line GBL, the first emission control line EL1, the second emission control line EL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. For example, the first driving voltage line VSL may be a low potential voltage line, the second driving voltage line VDL may be a high potential voltage line, and the third driving voltage line VIL may be an initialization voltage line. In such an embodiment, the first driving voltage VSS may be lower than the third driving voltage VINT, and the second driving voltage VDD may be higher than the third driving voltage VINT.

The first sub-pixel SP1 includes a plurality of transistors T1 to T6, a light-emitting element LE, a first capacitor CP1, and a second capacitor CP2.

The light-emitting element LE emits light in response to a driving current flowing through the channel of the first transistor T1. The emission amount of the light-emitting element LE may be proportional to the driving current. The light-emitting element LE may be disposed between a fourth transistor T4 and the first driving voltage line VSL. The first electrode of the light-emitting element LE may be connected to the drain electrode of the fourth transistor T4, and the second electrode thereof may be connected to the first driving voltage line VSL. The first electrode of the light-emitting element LE may be an anode electrode, and the second electrode of the light-emitting element LE may be a cathode electrode. The light-emitting element LE may be an organic light-emitting diode including a first electrode, a second electrode, and an organic light-emitting layer disposed between the first electrode and the second electrode, but the present disclosure is not limited thereto. For example, the light-emitting element LE may be an inorganic light-emitting element including a first electrode, a second electrode, and an inorganic semiconductor disposed between the first electrode and the second electrode, in which case the light-emitting element LE may be a micro light-emitting diode.

The first transistor T1 may be a driving transistor that controls a source-drain current (hereinafter referred to as “driving current”) flowing between the source electrode and the drain electrode thereof according to a voltage applied to the gate electrode thereof. The first transistor T1 includes a gate electrode connected to a first node N1, a source electrode connected to the drain electrode of a sixth transistor T6, and a drain electrode connected to a second node N2.

A second transistor T2 may be disposed between one electrode of the first capacitor CP1 and the data line DL. The second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1. The second transistor T2 includes a gate electrode connected to the write scan line GWL, a source electrode connected to the data line DL, and a drain electrode connected to the one electrode of the first capacitor CP1.

A third transistor T3 may be disposed between the first node N1 and the second node N2. The third transistor T3 is turned on by the write control signal of the write control line GCL to connect the first node N1 to the second node N2. For this reason, because the gate electrode and the source electrode of the first transistor T1 are connected, the first transistor T1 may operate like a diode. The third transistor T3 includes a gate electrode connected to the write control line GCL, a source electrode connected to the second node N2, and a drain electrode connected to the first node N1

The fourth transistor T4 may be connected between the second node N2 and a third node N3. The fourth transistor T4 is turned on by the first emission control signal of the first emission control line EL1 to connect the second node N2 to the third node N3. Accordingly, the driving current of the first transistor T1 may be supplied to the light-emitting element LE. The fourth transistor T4 includes a gate electrode connected to the first emission control line EL1, a source electrode connected to the second node N2, and a drain electrode connected to the third node N3.

A fifth transistor T5 may be disposed between the third node N3 and the third driving voltage line VIL. The fifth transistor T5 is turned on by the bias scan signal of the bias scan line GBL to connect the third node N3 to the third driving voltage line VIL. Accordingly, the third driving voltage VINT of the third driving voltage line VIL may be applied to the first electrode of the light-emitting element LE. The fifth transistor T5 includes a gate electrode connected to the bias scan line GBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 is turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 includes a gate electrode connected to the second emission control line EL2, a source electrode connected to the second driving voltage line VDL, and a drain electrode connected to the source electrode of the first transistor T1.

The first capacitor CP1 is formed between the first node N1 and the drain electrode of the second transistor T2. The first capacitor CP1 includes one electrode connected to the drain electrode of the second transistor T2 and the other electrode connected to the first node N1.

The second capacitor CP2 is formed between the gate electrode of the first transistor T1 and the second driving voltage line VDL. The second capacitor CP2 includes one electrode connected to the gate electrode of the first transistor T1 and the other electrode connected to the second driving voltage line VDL.

The first node N1 is a junction between the gate electrode of the first transistor T1, the drain electrode of the third transistor T3, the other electrode of the first capacitor CP1, and the one electrode of the second capacitor CP2. The second node N2 is a junction between the drain electrode of the first transistor T1, the source electrode of the third transistor T3, and the source electrode of the fourth transistor T4. The third node N3 is a junction between the drain electrode of the fourth transistor T4, the source electrode of the fifth transistor T5, and the first electrode of the light-emitting element LE.

Each of the first to sixth transistors T1 to T6 may be a metal-oxide-semiconductor field effect transistor (MOSFET). For example, each of the first to sixth transistors T1 to T6 may be a P-type MOSFET, but the present disclosure is not limited thereto. In another embodiment, each of the first to sixth transistors T1 to T6 may be an N-type MOSFET. In another embodiment, some of the first to sixth transistors T1 to T6 may be P-type MOSFETs, and each of the remaining transistors may be an N-type MOSFET.

Although FIG. 3 illustrates an embodiment in which the first sub-pixel SP1 includes six transistors T1 to T6 and two capacitors C1 and C2, it should be noted that the equivalent circuit diagram of the first sub-pixel SP1 is not limited to that shown in FIG. 3. For example, the number of transistors and the number of capacitors of the first sub-pixel SP1 are not limited to those shown in FIG. 3.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 3. Therefore, the description of the equivalent circuit diagram of the second sub-pixel SP2 and the equivalent circuit diagram of the third sub-pixel SP3 is not repeated in the present disclosure.

FIG. 4 is a layout diagram of a display panel according to one embodiment.

Referring to FIG. 4, the display area DAA of the display panel 100, according to one embodiment, includes the plurality of pixels PX arranged in a matrix form. The non-display area NDA of the display panel 100, according to one embodiment, includes the scan driver 610, the emission driver 620, the data driver 700, a first distribution circuit 710, a second distribution circuit 720, the first pad portion PDA1, and a second pad portion PDA2.

The scan driver 610 may be disposed on the first side of the display area DAA, and the emission driver 620 may be disposed on the second side of the display area DAA. For example, the scan driver 610 may be disposed on one side of the display area DAA in the first direction DR1, and the emission driver 620 may be disposed on the other side of the display area DAA in the first direction DR1. For example, the scan driver 610 may be disposed on the left side of the display area DAA, and the emission driver 620 may be disposed on the right side of the display area DAA. However, the present disclosure is not limited thereto, and in another embodiment, the scan driver 610 and the emission driver 620 may both be disposed on the first side or on the second side of the display area DAA.

The first pad portion PDA1 may include the plurality of first pads PD1 connected to pads or bumps of the circuit board 300 via a conductive adhesive member. The first pad portion PDA1 may be disposed on the third side of the display area DAA. For example, the first pad portion PDA1 may be disposed on one side of the display area DAA in the second direction DR2.

The first pad portion PDA1 may be disposed outside the data driver 700 in the second direction DR2. For example, the first pad portion PDA1 may be disposed closer to the edge of the display panel 100 than the data driver 700 is (e.g., the first pad portion PDA1 may be arranged between the edge of the display panel 100 and the data driver 700).

The second pad portion PDA2 may include a plurality of second pads PD2 corresponding to inspection pads used to test whether or not the display panel 100 operates normally. The plurality of second pads PD2 may be connected to a jig or a probe pin during an inspection process or may be connected to a circuit board for inspection. The circuit board for inspection may be a printed circuit board made of a rigid material or a flexible printed circuit board made of a flexible material.

The first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to the P (P being a positive integer of 2 or more) data lines DL, and as a result, the number of the plurality of first pads PD1 may be reduced. The first distribution circuit 710 may be disposed on the third side of the display area DAA of the display panel 100. For example, the first distribution circuit 710 may be disposed on one side of the display area DAA in the second direction DR2. For example, the first distribution circuit 710 may be disposed on the lower side of the display area DAA.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on the fourth side of the display area DAA of the display panel 100. For example, the second distribution circuit 720 may be disposed on the other side of the display area DAA in the second direction DR2. For example, the second distribution circuit 720 may be disposed on the upper side of the display area DAA.

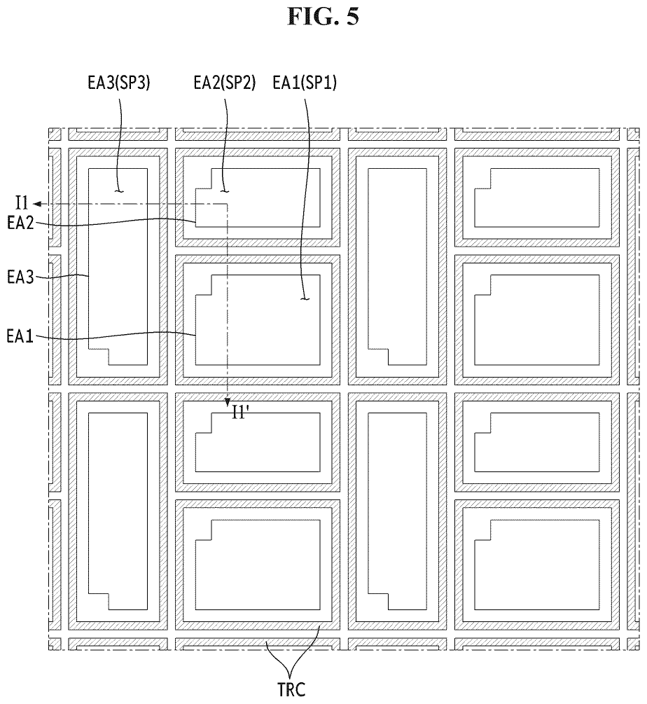

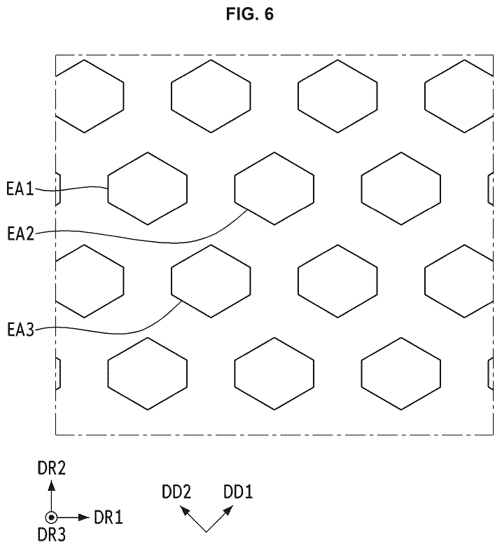

FIGS. 5 and 6 are layout diagrams of the display area shown in FIG. 4 according to various embodiments.

Referring to FIGS. 5 and 6, each of the pixels PX includes the first emission area EA1 that is an emission area of the first sub-pixel SP1, the second emission area EA2 that is an emission area of the second sub-pixel SP2, and the third emission area EA3 that is an emission area of the third sub-pixel SP3.

Each of the first emission area EA1, the second emission area EA2, and the third emission area EA3 may have a polygonal, circular, elliptical, or atypical shape in a plan view.

The maximum length of the third emission area EA3 in the first direction DR1 may be less than the maximum length of the first emission area EA1 in the first direction DR1 and the maximum length of the second emission area EA2 in the first direction DR1. The maximum length of the first emission area EA1 in the first direction DR1 and the maximum length of the second emission area EA2 in the first direction DR1 may be substantially the same.

The maximum length of the third emission area EA3 in the second direction DR2 may be greater than the maximum length of the first emission area EA1 in the second direction DR2 and the maximum length of the second emission area EA2 in the second direction DR2. The maximum length of the first emission area EA1 in the second direction DR2 may be greater than the maximum length of the second emission area EA2 in the second direction DR2.

The first emission area EA1, the second emission area EA2, and the third emission area EA3 may have, in a plan view, a hexagonal shape formed of six straight lines as shown in FIGS. 5 and 6, but the present disclosure is not limited thereto. The first emission area EA1, the second emission area EA2, and the third emission area EA3 may have a polygonal shape other than a hexagon, a circular shape, an elliptical shape, or an atypical shape in a plan view.

As shown in FIG. 5, in each of the plurality of pixels PX, the first emission area EA1 and the second emission area EA2 may be adjacent to each other in the second direction DR2. Further, the first emission area EA1 and the third emission area EA3 may be adjacent to each other in the first direction DR1. In addition, the second emission area EA2 and the third emission area EA3 may be adjacent to each other in the first direction DR1. The area of the first emission area EA1, the area of the second emission area EA2, and the area of the third emission area EA3 may be different.

In another embodiment, as shown in FIG. 6, the first emission area EA1 and the second emission area EA2 may be adjacent to each other in the first direction DR1, but the second emission area EA2 and the third emission area EA3 may be adjacent to each other in a first diagonal direction DD1, and the first emission area EA1 and the third emission area EA3 may be adjacent to each other in a second diagonal direction DD2. The first diagonal direction DD1 may be a direction between the first direction DR1 and the second direction DR2 and may refer to a direction inclined by 45 degrees with respect to the first direction DR1 and the second direction DR2, and the second diagonal direction DD2 may be a direction perpendicular to the first diagonal direction DD1.

The first emission area EA1 may emit light of a first color, the second emission area EA2 may emit light of a second color, and the third emission area EA3 may emit light of a third color. The light of the first color may be light in a blue wavelength band, the light of the second color may be light in a green wavelength band, and the light of the third color may be light in a red wavelength band. For example, the blue wavelength band may be a wavelength band of light having a main peak wavelength in a range of about 370 nm to about 460 nm, the green wavelength band may be a wavelength band of light having a main peak wavelength in a range of about 480 nm to about 560 nm, and the red wavelength band may be a wavelength band of light having a main peak wavelength in the range of about 600 nm to about 750 nm.

In the embodiments shown in FIGS. 5 and 6, each of the plurality of pixels PX includes three emission areas EA1, EA2, and EA3, but the present disclosure is not limited thereto. In other embodiments, each of the plurality of pixels PX may include four emission areas.

In addition, the layout of the emission areas of the plurality of pixels PX is not limited to those illustrated in FIGS. 5 and 6. For example, the emission areas of the plurality of pixels PX may be disposed in a stripe structure in which the emission areas are arranged in the first direction DR1, a PenTile® (a registered trademark of Samsung Display Co., Ltd.) structure in which the emission areas are arranged in a diamond shape, or a hexagonal structure in which the emission areas having, in a plan view, a hexagonal shape are arranged as shown in FIG. 6.

FIG. 7 is a cross-sectional view of the display panel shown in FIG. 5 taken along the line I1-I1′ in FIG. 5.

Referring to FIG. 7, the display panel 100 includes a semiconductor backplane SBP, a light-emitting element backplane EBP, a display element layer EML, an encapsulation layer TFE, an optical layer OPL, a cover layer CVL, and a polarizing plate POL.

The semiconductor backplane SBP includes the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 4.

The semiconductor substrate SSUB may be a silicon substrate, a germanium substrate, or a silicon-germanium substrate. The semiconductor substrate SSUB may be a substrate doped with a first type impurity. A plurality of well regions WA may be disposed on (or in) the top surface of the semiconductor substrate SSUB. The plurality of well regions WA may be regions doped with a second type impurity. The second type impurity may be different from the aforementioned first type impurity. For example, when the first type impurity is a p-type impurity, the second type impurity may be an n-type impurity. Alternatively, when the first type impurity is an n-type impurity, the second type impurity may be a p-type impurity.

Each of the plurality of well regions WA includes a source region SA corresponding to the source electrode of the pixel transistor PTR, a drain region DA corresponding to the drain electrode thereof, and a channel region CH disposed between the source region SA and the drain region DA.

A lower insulating film BINS may be disposed between a gate electrode GE and the well region WA. A side insulating film SINS may be disposed on the side surface of the gate electrode GE. The side insulating film SINS may be disposed on the lower insulating film BINS.

Each of the source region SA and the drain region DA may be a region doped with the first type impurity. The gate electrode GE of the pixel transistor PTR may overlap the well region WA in the third direction DR3. The channel region CH may overlap the gate electrode GE in the third direction DR3. The source region SA may be disposed on one side of the gate electrode GE, and the drain region DA may be disposed on the other side of the gate electrode GE.

Each of the plurality of well regions WA further includes a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the presence of the first low-concentration impurity region LDD1 and the second low-concentration impurity region LDD2. Therefore, the length of the channel region CH of each of the pixel transistors PTR may increase so that punch-through and hot carrier phenomena that might be caused by a short channel may be reduced or prevented.

A first semiconductor insulating film SINS1 may be disposed on the semiconductor substrate SSUB. The first semiconductor insulating film SINS1 may be formed of silicon carbonitride (SiCN) or a silicon oxide (SiOₓ)-based inorganic film, but the present disclosure is not limited thereto.

A second semiconductor insulating film SINS2 may be disposed on the first semiconductor insulating film SINS1. The second semiconductor insulating film SINS2 may be formed of a silicon oxide (SiOₓ)-based inorganic film, but the present disclosure is not limited thereto.

The plurality of contact terminals CTE may be disposed on the second semiconductor insulating film SINS2. Each of the plurality of contact terminals CTE may be connected to any one of the gate electrode GE, the source region SA, and the drain region DA of each of the pixel transistors PTR through a hole (e.g., an opening) penetrating (or extending through) the first semiconductor insulating film SINS1 and the second semiconductor insulating film INS2. The plurality of contact terminals CTE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

A third semiconductor insulating film SINS3 may be disposed on a side surface of each of the plurality of contact terminals CTE. The top surface of each of the plurality of contact terminals CTE may be exposed without being covered by the third semiconductor insulating film SINS3. The third semiconductor insulating film SINS3 may be formed of a silicon oxide (SiOₓ)-based inorganic film, but the present disclosure is not limited thereto.

The semiconductor substrate SSUB may be replaced with a glass substrate or a polymer resin substrate, such as polyimide. In such an embodiment, thin film transistors may be disposed on the glass substrate or the polymer resin substrate. The glass substrate may be a rigid substrate that does not bend (e.g., is not designed to bend), and the polymer resin substrate may be a flexible substrate that can be bent or curved.

The light-emitting element backplane EBP includes a plurality of conductive layers ML1 to ML8, a plurality of vias VA1 to VA9, and a plurality of insulating films INS1 to INS9. In addition, the light-emitting element backplane EBP includes a plurality of insulating films INS2 to INS8 disposed between the first to eighth conductive layers ML1 to ML8.

The first to eighth conductive layers ML1 to ML8 connect the plurality of contact terminals CTE exposed from the semiconductor backplane SBP to thereby implement the circuit of the first sub-pixel SP1 shown in, for example, FIG. 3. For example, the first to sixth transistors T1 to T6 are formed in the semiconductor backplane SBP, and the connection of the first to sixth transistors T1 to T6 and the first and second capacitors C1 and C2 is accomplished through the first to eighth conductive layers ML1 to ML8. In addition, the connection between the drain region corresponding to the drain electrode of the fourth transistor T4, the source region corresponding to the source electrode of the fifth transistor T5, and the first electrode of the light-emitting element LE is also accomplished through the first to eighth conductive layers ML1 to ML8.

The first insulating film INS1 may be disposed on the semiconductor backplane SBP. Each of the first vias VA1 may penetrate (e.g., may extend through) the first insulating film INS1 and may be connected to the contact terminal CTE exposed from the semiconductor backplane SBP. Each of the first conductive layers ML1 may be disposed on the first insulating film INS1 and may be connected to the first via VA1.

The second insulating film INS2 may be disposed on the first insulating film INS1 and the first conductive layers ML1. Each of the second vias VA2 may penetrate 1 (e.g., may extend through) the second insulating film INS2 and may be connected to the exposed first conductive layer ML1. Each of the second conductive layers ML2 may be disposed on the second insulating film INS2 and may be connected to the second via VA2.

The third insulating film INS3 may be disposed on the second insulating film INS2 and the second conductive layers ML2. Each of the third vias VA3 may penetrate (e.g., may extend through) the third insulating film INS3 and may be connected to the exposed second conductive layer ML2. Each of the third conductive layers ML3 may be disposed on the third insulating film INS3 and may be connected to the third via VA3.

A fourth insulating film INS4 may be disposed on the third insulating film INS3 and the third conductive layers ML3. Each of the fourth vias VA4 may penetrate (e.g., may extend through) the fourth insulating film INS4 and may be connected to the exposed third conductive layer ML3. Each of the fourth conductive layers ML4 may be disposed on the fourth insulating film INS4 and may be connected to the fourth via VA4.

A fifth insulating film INS5 may be disposed on the fourth insulating film INS4 and the fourth conductive layers ML4. Each of the fifth vias VA5 may penetrate (e.g., may extend through) the fifth insulating film INS5 and may be connected to the exposed fourth conductive layer ML4. Each of the fifth conductive layers ML5 may be disposed on the fifth insulating film INS5 and may be connected to the fifth via VA5.

A sixth insulating film INS6 may be disposed on the fifth insulating film INS5 and the fifth conductive layers ML5. Each of the sixth vias VA6 may penetrate (e.g., may extend through) the sixth insulating film INS6 and may be connected to the exposed fifth conductive layer ML5. Each of the sixth conductive layers ML6 may be disposed on the sixth insulating film INS6 and may be connected to the sixth via VA6.

A seventh insulating film INS7 may be disposed on the sixth insulating film INS6 and the sixth conductive layers ML6. Each of the seventh vias VA7 may penetrate (e.g., may extend through) the seventh insulating film INS7 and may be connected to the exposed sixth conductive layer ML6. Each of the seventh conductive layers ML7 may be disposed on the seventh insulating film INS7 and may be connected to the seventh via VA7.

An eighth insulating film INS8 may be disposed on the seventh insulating film INS7 and the seventh conductive layers ML7. Each of the eighth vias VA8 may penetrate (e.g., may extend through) the eighth insulating film INS8 and may be connected to the exposed seventh conductive layer ML7. Each of the eighth conductive layers ML8 may be disposed on the eighth insulating film INS8 and may be connected to the eighth via VA8.

The first to eighth conductive layers ML1 to ML8 and the first to eighth vias VA1 to VA8 may be formed of substantially the same material. The first to eighth conductive layers ML1 to ML8 and the first to eighth vias VA1 to VA8 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The first to eighth vias VA1 to VA8 may be made of substantially the same material. First to eighth insulating films INS1 to INS8 may be formed of a silicon oxide (SiOₓ)-based inorganic film, but the present disclosure is not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be greater than the thicknesses of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be approximately 1360 Å. The thickness of each of the second conductive layer ML2, the third conductive layer ML3, the fourth conductive layer ML4, the fifth conductive layer ML5, and the sixth conductive layer ML6 may be approximately 1440 Å. The thickness of each of the first via VA1, the second via VA2, the third via VA3, the fourth via VA4, the fifth via VA5, and the sixth via VA6 may be approximately 1150 Å.

The thickness of each of the seventh conductive layer ML7 and the eighth conductive layer ML8 may be greater than the thickness of each of the first conductive layer ML1, the second conductive layer ML2, the third conductive layer ML3, the fourth conductive layer ML4, the fifth conductive layer ML5, and the sixth conductive layer ML6. The thickness of the seventh conductive layer ML7 and the thickness of the eighth conductive layer ML8 may be greater than the thickness of the seventh via VA7 and the thickness of the eighth via VA8, respectively. The thickness of each of the seventh via VA7 and the eighth via VA8 may be greater than the thickness of each of the first via VA1, the second via VA2, the third via VA3, the fourth via VA4, the fifth via VA5, and the sixth via VA6. The thickness of the seventh conductive layer ML7 and the thickness of the eighth conductive layer ML8 may be substantially the same. For example, the thickness of each of the seventh conductive layer ML7 and the eighth conductive layer ML8 may be approximately 9000 Å. The thickness of each of the seventh via VA7 and the eighth via VA8 may be approximately 6000 Å.

A ninth insulating film INS9 may be disposed on the eighth insulating film INS8 and the eighth conductive layer ML8. The ninth insulating film INS9 may be formed of a silicon oxide (SiOₓ)-based inorganic film, but the present disclosure is not limited thereto.

Each of the ninth vias VA9 may penetrate (e.g., may extend through) the ninth insulating film INS9 and may be connected to the exposed eighth conductive layer ML8. The ninth vias VA9 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the ninth via VA9 may be approximately 16500 Å.

The display element layer EML may be disposed on the light-emitting element backplane EBP. The display element layer EML may include light-emitting elements LE each including a reflective electrode layer RL, tenth and eleventh insulating films INS10 and INS11, a tenth via VA10, the first electrode AND, a light-emitting stack IL, and a second electrode CAT; and a pixel defining film PDL.

The reflective electrode layer RL may be disposed on the ninth insulating film INS9. The reflective electrode layer RL may include at least one reflective electrode RL1, RL2, RL3, and RL4. For example, the reflective electrode layer RL may include first to fourth reflective electrodes RL1, RL2, RL3, and RL4 as shown in, for example, FIG. 7.

Each of the first reflective electrodes RL1 may be disposed on the ninth insulating film INS9 and may be connected to the ninth via VA9. The first reflective electrodes RL1 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first reflective electrodes RL1 may include titanium nitride (TiN).

Each of the second reflective electrodes RL2 may be disposed on the first reflective electrode RL1. The second reflective electrodes RL2 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the second reflective electrodes RL2 may include aluminum (Al).

Each of the third reflective electrodes RL3 may be disposed on the second reflective electrode RL2. The third reflective electrodes RL3 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the third reflective electrodes RL3 may include titanium nitride (TiN).

Each of the fourth reflective electrodes RL4 may be disposed on the third reflective electrode RL3. The fourth reflective electrodes RL4 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the fourth reflective electrodes RL4 may include titanium (Ti).

Because the second reflective electrode RL2 is an electrode that substantially reflects light from the light-emitting elements LE, the thickness of the second reflective electrode RL2 may be greater than the thickness of each of the first reflective electrode RL1, the third reflective electrode RL3, and the fourth reflective electrode RL4. For example, the thickness of each of the first reflective electrode RL1, the third reflective electrode RL3, and the fourth reflective electrode RL4 may be approximately 100 Å, and the thickness of the second reflective electrode RL2 may be approximately 850 Å.

The tenth insulating film INS10 may be disposed on the ninth insulating film INS9. The tenth insulating film INS10 may be disposed between the reflective electrode layers RL adjacent to each other in a horizontal direction. The tenth insulating film INS10 may be formed of a silicon oxide (SiOₓ)-based inorganic film, but the present disclosure is not limited thereto.

The eleventh insulating film INS11 may be disposed on the tenth insulating film INS10 and the reflective electrode layer RL. The eleventh insulating film INS11 may be formed of a silicon oxide (SiOₓ)-based inorganic film, but the present disclosure is not limited thereto. The tenth insulating film INS10 and the eleventh insulating film INS11 may be an optical auxiliary layer through which light reflected by the reflective electrode layer RL passes from among light emitted from the light-emitting elements LE.

To match the resonance distance of the light emitted from the light-emitting elements LE in at least one of the first sub-pixel SP1, the second sub-pixel SP2, or the third sub-pixel SP3, the tenth insulating film INS10 or the eleventh insulating film INS11 may not be disposed under the first electrode AND. For example, the first electrode AND of the first sub-pixel SP1 may be directly disposed on the reflective electrode layer RL. The eleventh insulating film INS11 may be disposed under the first electrode AND of the second sub-pixel SP2. The tenth insulating film INS10 and the eleventh insulating film INS11 may be disposed under the first electrode AND of the third sub-pixel SP3.

In summary, the distance between the first electrode AND and the reflective electrode layer RL may be different in the first sub-pixel SP1, the second sub-pixel SP2, and the third sub-pixel SP3, respectively. For example, to adjust the distance from the reflective electrode layer RL to the first electrode AND according to the main wavelength of the light emitted from each of the first sub-pixel SP1, the second sub-pixel SP2, and the third sub-pixel SP3, the presence or absence of the tenth insulating film INS10 and the eleventh insulating film INS11 may be set in each of the first sub-pixel SP1, the second sub-pixel SP2, and the third sub-pixel SP3. For example, the distance between the first electrode AND and the reflective electrode layer RL in the third sub-pixel SP3 may be greater than the distance between the first electrode AND and the reflective electrode layer RL in the second sub-pixel SP2 and the distance between the first electrode AND and the reflective electrode layer RL in the first sub-pixel SP1, and the distance between the first electrode AND and the reflective electrode layer RL in the second sub-pixel SP2 may be greater than the distance between the first electrode AND and the reflective electrode layer RL in the first sub-pixel SP1. The present disclosure, however, is not limited to the above examples.

In addition, although the tenth insulating film INS10 and the eleventh insulating film INS11 are illustrated in the embodiment shown in FIG. 7, a twelfth insulating film disposed under the first electrode AND of the first sub-pixel SP1 may be added. In such an embodiment, the eleventh insulating film INS11 and the twelfth insulating film may be disposed under the first electrode AND of the second sub-pixel SP2, and the tenth insulating film INS10, the eleventh insulating film INS11, and the twelfth insulating film may be disposed under the first electrode AND of the third sub-pixel SP3.

Each of the tenth vias VA10 may penetrate (e.g., may extend through) the tenth insulating film INS10 and/or the eleventh insulating film INS11 in the second sub-pixel SP2 and the third sub-pixel SP3 and may be connected to the exposed reflective electrode layer RL. The tenth vias VA10 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the tenth via VA10 in the second sub-pixel SP2 may be less than the thickness of the tenth via VA10 in the third sub-pixel SP3.

The first electrode AND of each of the light-emitting elements LE may be disposed on the tenth insulating film INS10 and connected to the tenth via VA10. The first electrode AND of each of the light-emitting elements LE may be connected to the drain region DA or source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light-emitting elements LE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first electrode AND of each of the light-emitting elements LE may be titanium nitride (TiN).

The pixel defining film PDL may be disposed on a portion of the first electrode AND of each of the light-emitting elements LE. The pixel defining film PDL may cover the edge of the first electrode AND of each of the light-emitting elements LE. The pixel defining film PDL may partition the first emission areas EA1, the second emission areas EA2, and the third emission areas EA3 from each other.

The first emission area EA1 may be defined as an area in which the first electrode AND, the light-emitting stack IL, and the second electrode CAT are sequentially stacked in the first sub-pixel SP1 to emit light. The second emission area EA2 may be defined as an area in which the first electrode AND, the light-emitting stack IL, and the second electrode CAT are sequentially stacked in the second sub-pixel SP2 to emit light. The third emission area EA3 may be defined as an area in which the first electrode AND, the light-emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be disposed on the edge of the first electrode AND of each of the light-emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed of a silicon oxide (SiOₓ)-based inorganic film, but the present disclosure is not limited thereto. The first pixel defining film PDL1, the second pixel defining film PDL2, and the third pixel defining film PDL3 may each have a thickness of about 500 Å.

When the first pixel defining film PDL1, the second pixel defining film PDL2, and the third pixel defining film PDL3 are formed as one pixel defining film, the height of the one pixel defining film is relatively high so that a first encapsulation inorganic film TFE1 may be cut off due to step coverage. Step coverage refers to the ratio of the degree of thin film coated on an inclined portion to the degree of thin film coated on a flat portion. The lower the step coverage, the more likely it is that the thin film will be cut off at inclined portions.

Therefore, to reduce or prevent the likelihood of the first encapsulation inorganic film TFE1 being cut off due to the step coverage, the first pixel defining film PDL1, the second pixel defining film PDL2, and the third pixel defining film PDL3 may have a cross-sectional structure having a stepped portion. For example, the width of the first pixel defining film PDL1 may be greater than the width of the second pixel defining film PDL2 and the width of the third pixel defining film PDL3, and the width of the second pixel defining film PDL2 may be greater than the width of the third pixel defining film PDL3. The width of the first pixel defining film PDL1 refers to the horizontal length of the first pixel defining film PDL1 defined in the first direction DR1 and the second direction DR2.

The light-emitting stack IL may include a plurality of intermediate layers. The light-emitting stack IL includes a first stack layer IL1, a second stack layer IL2, and a third stack layer IL3 that emit different lights (e.g., different color lights). The first stack layer IL1, the second stack layer IL2, and the third stack layer IL3 are discontinuous between adjacent sub-pixels.

The first stack layer IL1 may have a structure in which a first hole transport layer, a first organic light-emitting layer configured to emit light of the first color, and a first electron transport layer are sequentially stacked. The first stack layer IL1 is disposed on the first electrodes AND and the pixel defining film PDL in the first emission area EA1 of the first sub-pixel SP1.

The second stack layer IL2 may have a structure in which a second hole transport layer, a second organic light-emitting layer configured to emit light of the third color, and a second electron transport layer are sequentially stacked. The second stack layer IL2 is disposed on the first electrodes AND and the pixel defining film PDL in the second emission area EA2 of the second sub-pixel SP2.

The third stack layer IL3 may have a structure in which a third hole transport layer, a third organic light-emitting layer configured to emit light of the second color, and a third electron transport layer are sequentially stacked. The third stack layer IL3 is disposed on the first electrodes AND and the pixel defining film PDL in the third emission area EA3 of the third sub-pixel SP3.

The second electrode CAT may be disposed on the third stack layer IL3 and the pixel defining film PDL. The second electrode CAT may be formed of a transparent conductive material (TCO), such as ITO or IZO, that can transmit light or a semi-transmissive conductive material, such as magnesium (Mg), silver (Ag), or an alloy of Mg and Ag. When the second electrode CAT is formed of a semi-transmissive conductive material, the light emission efficiency may be improved in each of the first to third sub-pixels SP1, SP2, and SP3 due to a micro-cavity effect.

The encapsulation layer TFE may be disposed on the display element layer EML. The encapsulation layer TFE may include at least one inorganic film TFE1 and TFE2 to reduce or prevent oxygen or moisture from permeating into the display element layer EML. For example, the encapsulation layer TFE may include the first encapsulation inorganic film TFE1 and a second encapsulation inorganic film TFE2.

The first encapsulation inorganic film TFE1 may be disposed on the second electrode CAT. The first encapsulation inorganic film TFE1 may be formed as a multilayer structure in which one or more inorganic films selected from silicon nitride (SiNₓ), silicon oxy nitride (SiON), and silicon oxide (SiOₓ) are alternately stacked. The first encapsulation inorganic film TFE1 may be formed by a chemical vapor deposition (CVD) process.

The second encapsulation inorganic film TFE2 may be disposed on the first encapsulation inorganic film TFE1. The second encapsulation inorganic film TFE2 may be formed of titanium oxide (TiOₓ) or aluminum oxide (AlOₓ), but the present disclosure is not limited thereto. The second encapsulation inorganic film TFE2 may be formed by an atomic layer deposition (ALD) process. The thickness of the second encapsulation inorganic film TFE2 may be less than the thickness of the first encapsulation inorganic film TFE1.

An organic film APL may increase the interfacial adhesion between the encapsulation layer TFE and the cover layer CVL. The organic film APL may be an organic film, such as acrylic resin, epoxy resin, phenolic resin, polyamide resin, or polyimide resin.

The cover layer CVL may be disposed on the organic film APL. The cover layer CVL may be a glass substrate or a polymer resin.

The polarizing plate POL may be disposed on one surface of the cover layer CVL. The polarizing plate POL may reduce or prevent visibility degradation caused by reflection of external light. The polarizing plate POL may include a linear polarizing plate and a phase retardation film. For example, the phase retardation film may be a λ/4 plate (quarter-wave plate), but the present disclosure is not limited thereto.

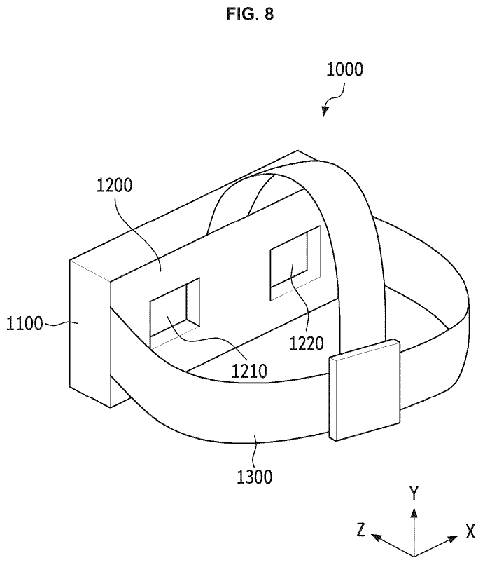

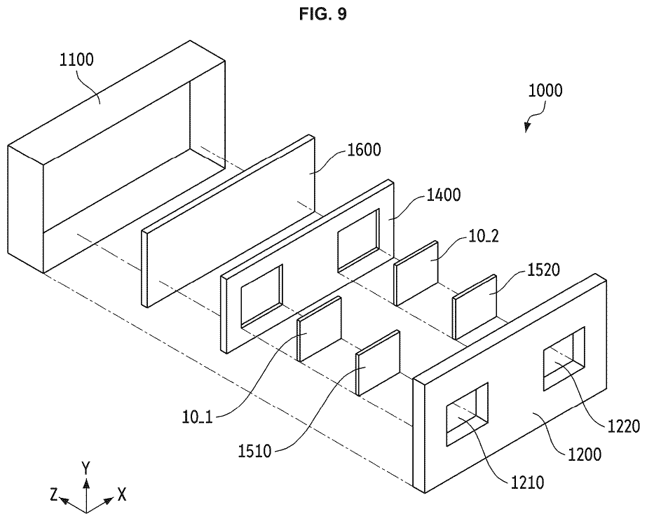

FIG. 8 is a perspective view of a head mounted display according to one embodiment. FIG. 9 is an exploded perspective view of the head mounted display shown in FIG. 8.

Referring to FIGS. 8 and 9, a head mounted display 1000, according to one embodiment, includes a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 provides an image to the user's left eye, and the second display device 10_2 provides an image to the user's right eye. Because each of the first display device 10_1 and the second display device 10_2 is substantially the same as the display device 10 described in conjunction with FIGS. 1 and 2, description of the first display device 10_1 and the second display device 10_2 will be omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first display device 10_1 and the control circuit board 1600 and between the second display device 10_2 and the control circuit board 1600. The middle frame 1400 supports and fixes the first display device 10_1, the second display device 10_2, and the control circuit board 1600.

The control circuit board 1600 may be disposed between the middle frame 1400 and the display device housing 1100. The control circuit board 1600 may be connected to the first display device 10_1 and the second display device 10_2 through the connector. The control circuit board 1600 may convert an image source inputted from the outside into the digital video data DATA and may transmit the digital video data DATA to the first display device 10_1 and the second display device 10_2 through the connector.

The control circuit board 1600 may transmit the digital video data DATA corresponding to a left-eye image optimized for the user's left eye to the first display device 10_1 and may transmit the digital video data DATA corresponding to a right-eye image optimized for the user's right eye to the second display device 10_2. In another embodiment, the control circuit board 1600 may transmit the same digital video data DATA to the first display device 10_1 and the second display device 10_2.

The display device housing 1100 accommodates the first display device 10_1, the second display device 10_2, the middle frame 1400, the first optical member 1510, the second optical member 1520, and the control circuit board 1600. The housing cover 1200 is disposed to cover one open surface of the display device housing 1100. The housing cover 1200 may include the first eyepiece 1210 at where the user's left eye is located and the second eyepiece 1220 at where the user's right eye is located. FIGS. 8 and 9 illustrate an embodiment in which the first eyepiece 1210 and the second eyepiece 1220 are separately disposed, but the present disclosure is not limited thereto. In another embodiment, the first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image displayed by the first display device 10_1 magnified as a virtual image by the first optical member 1510 and may view, through the second eyepiece 1220, the image displayed by the second display device 10_2 magnified as a virtual image by the second optical member 1520.

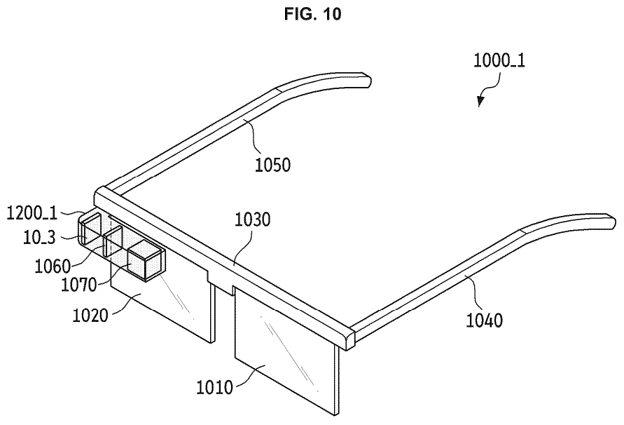

The head mounted band 1300 secures the display device housing 1100 to the user's head such that the first eyepiece 1210 and the second eyepiece 1220 of the housing cover 1200 remain located on the user's left and right eyes, respectively. When the display device housing 1200 is implemented to be lightweight and compact, the head mounted display 1000 may be provided with, as shown in FIG. 10, an eyeglass frame instead of the head mounted band 1300.

In addition, the head mounted display 1000 may further include a battery for supplying power, an external memory slot for accommodating an external memory, and an external connection port and a wireless communication module for receiving an image source (or image data). The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 10 is a perspective view of a head mounted display according to one embodiment.

Referring to FIG. 10, a head mounted display 1000_1, according to one embodiment, may be an eyeglasses-type display device in which a display device housing 1200_1 is implemented in a lightweight and compact manner. The head mounted display 1000_1, according to one embodiment, may include a display device 10_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 10_3, the optical member 1060, and the optical path changing member 1070. The image displayed on the display device 10_3 may be magnified by the optical member 1060 and may be provided to the user's right eye through the right eye lens 1020 after the optical path thereof is changed by the optical path changing member 1070. As a result, the user may view an augmented reality image, through the right eye, in which a virtual image displayed by the display device 10_3 and a real image seen through the right eye lens 1020 are combined.

FIG. 10 illustrates an embodiment in which the display device housing 1200_1 is disposed at the right end of the support frame 1030, but the present disclosure is not limited thereto. For example, the display device housing 1200_1 may be disposed at the left end of the support frame 1030, and in such an embodiment, the image of the display device 10_3 may be provided to the user's left eye. In another embodiment, the display device housing 1200_1 may be disposed at both the left and right ends of the support frame 1030, and such an embodiment, the user may view the image displayed on the display device 10_3 through both the left and right eyes.

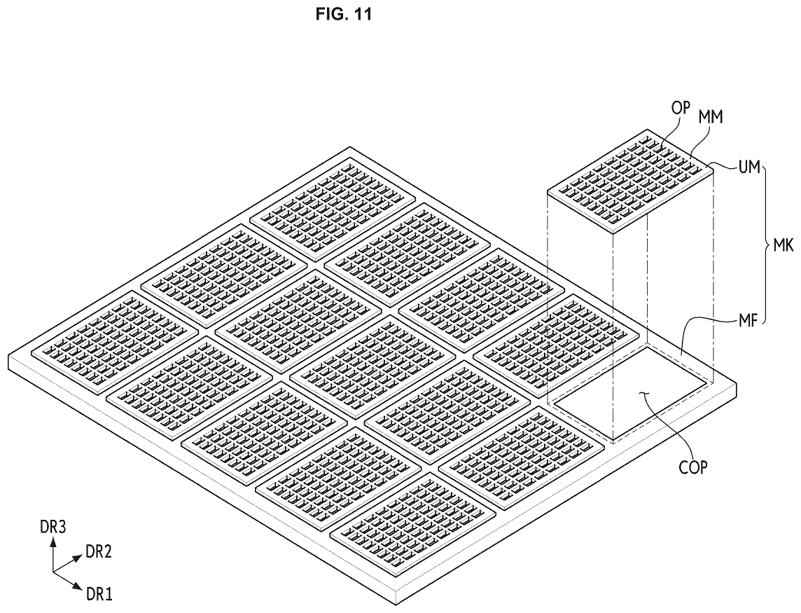

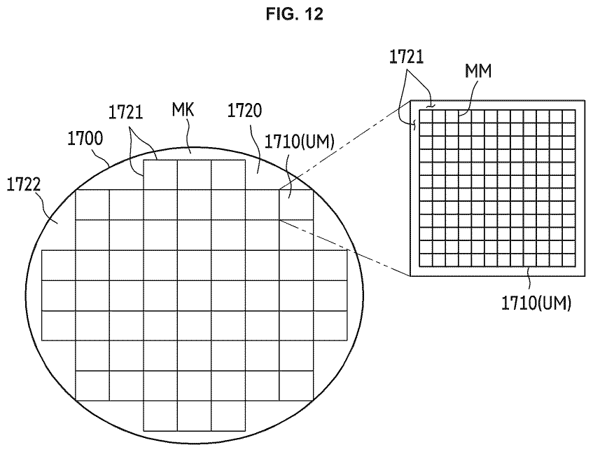

FIG. 11 is a perspective view of a mask according to one embodiment. FIG. 12 is a schematic plan view of a mask according to one embodiment. FIG. 11 shows a perspective view of a state in which one unit mask UM is separated from a plurality of unit masks. The mask, according to one embodiment, shown in FIGS. 11 and 12 may be used in the process of depositing at least a portion of the light-emitting stack IL described above with reference to FIG. 7. For example, the light-emitting stack IL may be configured to emit a different color in each of the sub-pixels SP1, SP2, and SP3.

Referring to FIGS. 11 and 12, a mask MK, according to one embodiment, may be a shadow mask in which a mask membrane MM is disposed on a silicon substrate 1700. The mask MK, according to one embodiment, may be referred to as a “silicon mask.”

According to one embodiment, the mask MK may include the silicon substrate 1700 and the mask membrane MM disposed on the silicon substrate 1700. The mask membrane MM may be disposed in cell regions 1710 arranged in a matrix form, and each cell region 1710 may be surrounded (e.g., surrounded along its periphery) by a mask lip region 1721. The mask lip region 1721 may have a portion of the silicon substrate disposed therein and may support the mask membrane MM.

The mask membrane MM may be a portion of the unit mask UM disposed in each of the plurality of cell regions 1710.

The silicon substrate 1700 may have the plurality of cell regions 1710 and a mask frame region 1720 excluding the plurality of cell regions 1710. The mask frame region 1720 may include the mask lip region 1721 surrounding each cell region 1710 and an outer frame region 1722 disposed at the outermost edge of the silicon substrate 1700. A mask frame MF may be disposed in the mask frame region 1720, and the mask frame MF may include a mask lip surrounding the cell region 1710.

The mask lip region 1721 may be a region that partitions the plurality of cell regions 1710. For example, the plurality of cell regions 1710 may be arranged in a matrix form, and the mask lip disposed in the mask lip region 1721 may be disposed to surround (e.g., extend around a periphery of) the outer edge of the mask membrane MM disposed in each cell region 1710.

A cell opening COP and the unit mask UM for masking at least a portion of the cell opening COP may be disposed in each of the plurality of cell regions 1710 of the silicon substrate 1700.

The plurality of cell openings COP may penetrate (e.g., may extend through) the mask frame MF along a thickness direction (e.g., the third direction DR3) of the mask MK. The plurality of cell openings COP may be formed by etching a portion of the silicon substrate 1700 from the rear direction.

Each unit mask UM may include the mask membrane MM, and the mask membrane MM may have a mask opening.

The mask opening in the mask membrane MM may be referred to as “hole” or “mask hole.” The mask openings may penetrate (e.g., may extend through) the unit masks UM along the thickness direction (e.g., the third direction DR3) of the mask MK.

One unit mask UM may be used in the deposition process of one display panel 100. In the present disclosure, the term “unit mask UM” may be interchangeable with a term such as a “mask unit UM.”

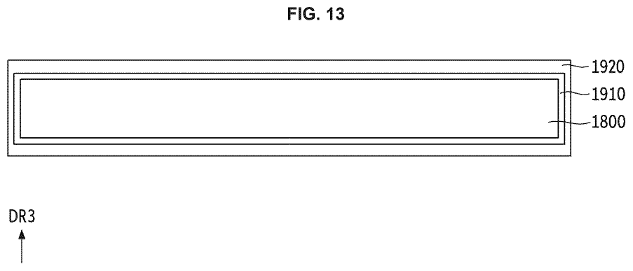

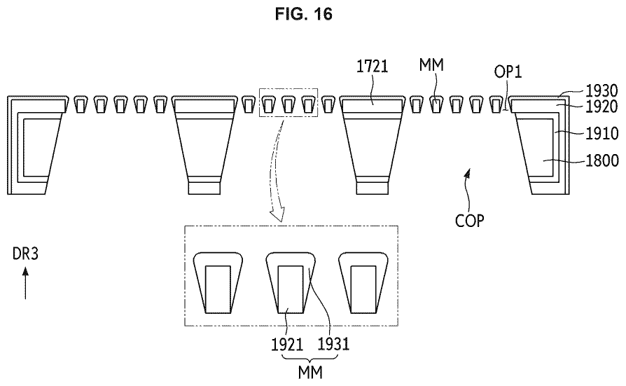

FIGS. 13 to 16 are cross-sectional views showing steps of a method of manufacturing a mask according to one embodiment. For example, FIG. 16 may be a cross-sectional view in which a portion of the mask according to one embodiment is cut, and FIGS. 13 to 16 may be diagrams sequentially illustrating steps of a process of manufacturing the mask shown in FIG. 16.

Hereinafter, a method of manufacturing a mask, according to one embodiment, will be described with reference to FIGS. 13 to 16.

Referring to FIG. 13, a substrate 1800 (e.g., 1700 in FIG. 12) may be provided. The substrate 1800 may include (or may contain) silicon (Si). The substrate 1800 may be referred to as “body substrate” or “membrane substrate” but is not limited thereto.

When the substrate 1800 is provided, an inorganic film 1910 and 1920 may be deposited on the substrate 1800. The inorganic film 1910 and 1920 may be deposited on the entire surface of (e.g., may encapsulate) the substrate 1800. For example, the inorganic film 1910 and 1920 may be deposited on the front surface, the side surface, and the rear surface of the substrate 1800.

According to one embodiment, the inorganic film 1910 and 1920 may include a single film. For example, the inorganic film 1910 and 1920 may include a first inorganic film 1910, and the first inorganic film 1910 may include (or may contain) at least one material selected from silicon (Si), silicon nitride (SiNₓ), silicon oxynitride (SiON), silicon oxide (SiOₓ), titanium oxide (TiOₓ), amorphous silicon (a-Si), and aluminum oxide (AlOₓ).

According to one embodiment, the inorganic film 1910 and 1920 may include multiple films. For example, the inorganic film includes the first inorganic film 1910 and a second inorganic film 1920 disposed on the first inorganic film 1910. The first inorganic film 1910 may contain silicon oxide (SiOₓ), and the second inorganic film 1920 may contain silicon nitride (SiNₓ). However, the material of each of the first inorganic film 1910 and the second inorganic film 1920 is not limited thereto. For example, each of the first inorganic film 1910 and the second inorganic film 1920 may contain at least one material selected from silicon (Si), silicon nitride (SiNₓ), silicon oxynitride (SiON), silicon oxide (SiOₓ), titanium oxide (TiOₓ), amorphous silicon (a-Si), and aluminum oxide (AlOₓ).

Hereinafter, an embodiment in which the first inorganic film 1910 and the second inorganic film 1920 are deposited on the substrate 1800 will be described.

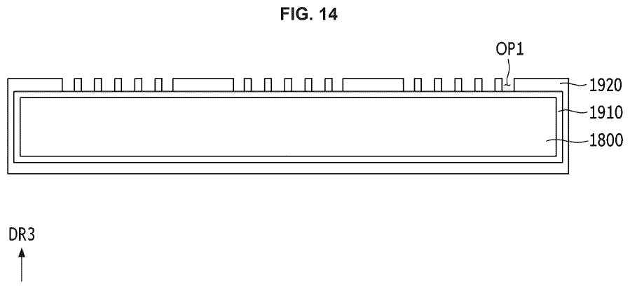

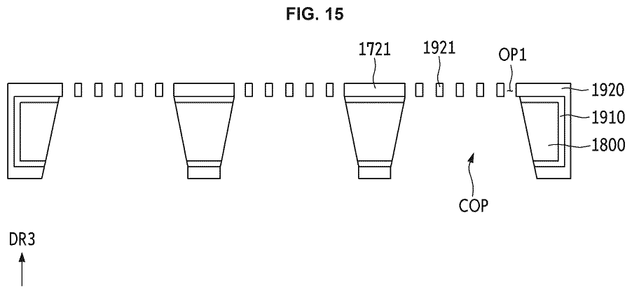

Referring to FIG. 14, the second inorganic film 1920 is patterned to form a second inorganic film pattern 1921 (see, e.g., FIG. 15) having a plurality of openings OP1. For example, as described with reference to FIG. 12, the plurality of cell regions 1710 are defined in the substrate 1800. A portion of the second inorganic film 1920 corresponding to the cell region 1710 of the substrate 1800 is patterned, and accordingly, the plurality of second inorganic film patterns 1921 are formed. The second inorganic film pattern 1921 becomes a portion of the mask membrane MM (see, e.g., FIG. 16) after the mask manufacturing process is completed.

The process of patterning the second inorganic film 1920 may include the following processes as a dry etching process for the second inorganic film 1920. A photoresist pattern is formed on the second inorganic film 1920. Subsequently, a portion of the second inorganic film 1920 located in the cell region 1710 is etched by using the photoresist pattern as a mask. Accordingly, the second inorganic film 1920 overlapping the photoresist pattern remains to become the second inorganic film pattern 1921, and the etched portion etched by using the photoresist pattern as a mask becomes the openings OP1 in the mask membrane MM.

Referring to FIG. 15, the second inorganic film 1920, the substrate 1800, and the first inorganic film 1910 are etched from the lower direction of the substrate 1800 to form the cell openings COP exposing the second inorganic film pattern 1921. The process of forming the cell openings COP includes a wet etching process of patterning the substrate 1800 containing silicon (Si) and the first inorganic film 1910 containing silicon oxide (SiOₓ).

Referring to FIG. 16, a third inorganic film 1930 may be deposited on the entire surface of the substrate 1800 including the second inorganic film pattern 1921. For example, the third inorganic film 1930 covers the top surface and the side surface of the second inorganic film pattern 1921. In the step of depositing the third inorganic film 1930, the second inorganic film pattern 1921 and the third inorganic film 1930 (e.g., a third inorganic film pattern 1931) deposited on the surface of the second inorganic film pattern 1921 form the mask membrane MM having a reverse tapered shape.

The third inorganic film 1930 may be deposited by using a chemical vapor deposition (CVD) method, but the present disclosure is not limited thereto. For example, the third inorganic film 1930 may be deposited by using an atomic layer deposition (ALD) method.

According to one embodiment, the material of the third inorganic film 1930 may be the same as the material of the first inorganic film 1910 or the material of the second inorganic film 1920. For example, the third inorganic film 1930 includes (or contains) silicon oxide (SiOₓ) or the second inorganic film 1920 includes (or contains) silicon nitride (SiNₓ).

According to one embodiment, the third inorganic film 1930 may include (or contain) at least one material selected from silicon (Si), silicon nitride (SiNₓ), silicon oxynitride (SiON), silicon oxide (SiOₓ), titanium oxide (TiOₓ), amorphous silicon (a-Si), and aluminum oxide (AlOₓ).

The third inorganic film 1930 may have a non-uniform thickness when deposited on the surface of the second inorganic film pattern 1921 due to differences in step coverage characteristics between the top surface and the side surface of the second inorganic film pattern 1921. For example, the deposition thickness of the third inorganic film 1930 (e.g., the third inorganic film pattern 1931) on the side surface of the second inorganic film pattern 1921 may be less than the deposition thickness of the third inorganic film 1930 on the top surface of the second inorganic film pattern 1921.

According to one embodiment, the deposition thickness of the third inorganic film 1930 (e.g., the third inorganic film pattern 1931) on the side surface of the second inorganic film pattern 1921 increases as it approaches the top surface of the second inorganic film pattern 1921. For example, the deposition thickness of the third inorganic film 1930 may increase in the third direction in which the top surface of the second inorganic film pattern 1921 faces. Accordingly, the cross-sectional structure of the mask membrane including the second inorganic film pattern 1921 and the third inorganic film 1930 (e.g., the third inorganic film pattern 1931) deposited thereon has a reverse tapered shape.

In accordance with the deposition mask and the method of manufacturing the same according to embodiments, because the cross-sectional structure of the mask membrane MM has a reverse tapered shape, shadow defects and deposition material buildup on the mask may be reduced during the deposition process using the mask. As a result, pixel position accuracy (PPA) is improved, thereby improving reliability.

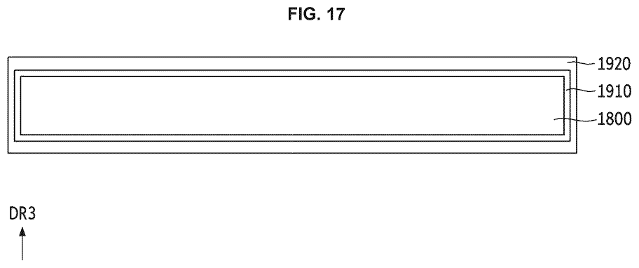

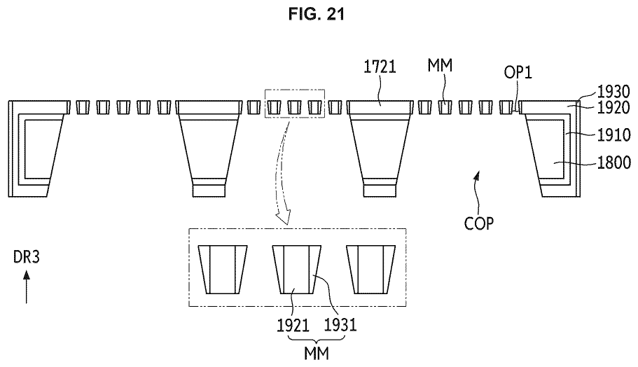

FIGS. 17 to 21 are cross-sectional views showing steps of a method of manufacturing a mask according to another embodiment. For example, FIG. 21 may be a cross-sectional view in which a portion of the mask according to another embodiment is cut, and FIGS. 17 to 21 may be diagrams sequentially showing steps of a process of manufacturing the mask shown in FIG. 21.

Hereinafter, a method of manufacturing a mask according to another embodiment will be described with reference to FIGS. 17 to 21.

Referring to FIG. 17, a substrate 1800 (e.g., 1700 in FIG. 12) may be provided. The substrate 1800 may include (or may contain) silicon (Si). The substrate 1800 may be referred to as “body substrate” or “membrane substrate” but is not limited thereto.

When the substrate 1800 is provided, an inorganic film 1910 and 1920 may be deposited on the substrate 1800. The inorganic film 1910 and 1920 may be deposited on the entire surface of (e.g., may encapsulate) the substrate 1800. For example, the inorganic film 1910 and 1920 may be deposited on the front surface, the side surface, and the rear surface of the substrate 1800.

According to one embodiment, the inorganic film 1910 and 1920 may be a single film. For example, the inorganic film 1910 and 1920 may include a first inorganic film 1910, and the first inorganic film 1910 may include (or may contain) at least one material selected from silicon (Si), silicon nitride (SiNₓ), silicon oxynitride (SiON), silicon oxide (SiOₓ), titanium oxide (TiOₓ), amorphous silicon (a-Si), and aluminum oxide (AlOₓ).

According to one embodiment, the inorganic film 1910 and 1920 may include multiple films. For example, the inorganic film includes the first inorganic film 1910 and a second inorganic film 1920 disposed on the first inorganic film 1910. The first inorganic film 1910 may include (or may contain) silicon oxide (SiOₓ), and the second inorganic film 1920 may contain silicon nitride (SiNₓ). However, the material of each of the first inorganic film 1910 and the second inorganic film 1920 is not limited thereto. For example, each of the first inorganic film 1910 and the second inorganic film 1920 may include (or may contain) at least one material selected from silicon (Si), silicon nitride (SiNₓ), silicon oxynitride (SiON), silicon oxide (SiOₓ), titanium oxide (TiOₓ), amorphous silicon (a-Si), and aluminum oxide (AlOₓ).

Hereinafter, an embodiment in which the first inorganic film 1910 and the second inorganic film 1920 are deposited on the substrate 1800 will be described.

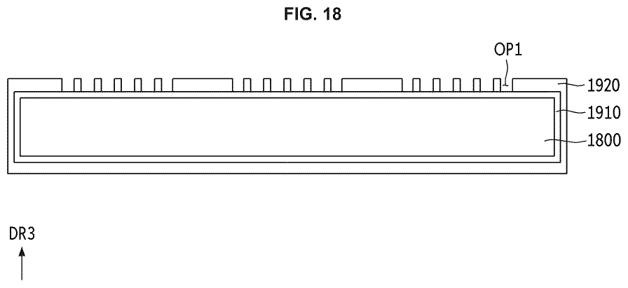

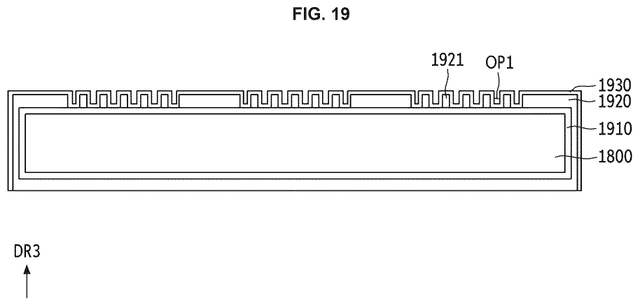

Referring to FIG. 18, the second inorganic film 1920 is patterned to form a second inorganic film pattern 1921 (see, e.g., FIG. 19) having a plurality of openings OP1. For example, as described with reference to FIG. 12, the plurality of cell regions 1710 are defined in the substrate 1800. A portion of the second inorganic film 1920 corresponding to the cell region 1710 of the substrate 1800 is patterned, and accordingly, the plurality of second inorganic film patterns 1921 are formed. The second inorganic film pattern 1921 becomes a portion of the mask membrane MM (see, e.g., FIG. 21) after the mask manufacturing process is completed.

The process of patterning the second inorganic film 1920 may include the following processes as a dry etching process for the second inorganic film 1920. A photoresist pattern is formed on the second inorganic film 1920. Subsequently, a portion of the second inorganic film 1920 located in the cell region 1710 is etched using the photoresist pattern as a mask. Accordingly, the second inorganic film 1920 overlapping the photoresist pattern remains to become the second inorganic film pattern 1921, and the portion etched by using the photoresist pattern as a mask becomes the openings OP1 in the mask membrane MM.

Referring to FIG. 19, a third inorganic film 1930 may be deposited on the entire surface of the substrate 1800 including the second inorganic film pattern 1921. For example, the third inorganic film 1930 (e.g., the third inorganic film pattern 1931) covers the top and side surfaces of the second inorganic film pattern 1921.

The third inorganic film 1930 may be deposited by using a chemical vapor deposition (CVD) method, but the present disclosure is not limited thereto. For example, the third inorganic film 1930 may be deposited by using an atomic layer deposition (ALD) method.

According to one embodiment, the material of the third inorganic film 1930 may be the same as the material of the first inorganic film 1910 or the material of the second inorganic film 1920. For example, the third inorganic film 1930 includes (or contains) silicon oxide (SiOₓ) or the second inorganic film 1920 includes (or contains) silicon nitride (SiNₓ).

According to one embodiment, the third inorganic film 1930 may include (or may contain) at least one material selected from silicon (Si), silicon nitride (SiNₓ), silicon oxynitride (SiON), silicon oxide (SiOₓ), titanium oxide (TiOₓ), amorphous silicon (a-Si), and aluminum oxide (AlOₓ).

The third inorganic film 1930 may have a non-uniform thickness when deposited on the surface of the second inorganic film pattern 1921 due to differences in step coverage characteristics between the top surface and the side surface of the second inorganic film pattern 1921. For example, the deposition thickness of the third inorganic film 1930 (e.g., the third inorganic film pattern 1931) on the side surface of the second inorganic film pattern 1921 may be less than the deposition thickness of the third inorganic film 1930 (e.g., the third inorganic film pattern 1931) on the top surface of the second inorganic film pattern 1921.

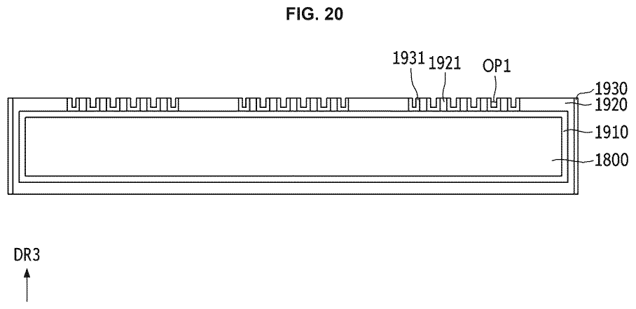

Referring to FIG. 20, the top surface of the substrate 1800 is polished to remove the third inorganic film 1930 (e.g., the third inorganic film pattern 1931) deposited on the top surface of the second inorganic film pattern 1921. Accordingly, only portions of the third inorganic film 1930 (e.g., the third inorganic film pattern 1931) deposited in the openings OP1 and on the side surface of the second inorganic film pattern 1921 remain.

According to one embodiment, the process of polishing the top surface of the substrate 1800 to remove the third inorganic film 1930 deposited on the top surface of the second inorganic film pattern 1921 may include a chemical mechanical polishing (CMP) process.

Referring to FIG. 21, the second inorganic film 1920, the substrate 1800, and the first inorganic film 1910 are etched from the lower direction of the substrate 1800 to form the cell openings COP exposing the second inorganic film pattern 1921 and the openings OP1 in the second inorganic film pattern 1921. To expose the openings OP1 in the second inorganic film pattern 1921, a portion of the third inorganic film 1930 positioned in the openings OP1 of the second inorganic film pattern 1921 may be etched.

According to one embodiment, the process of forming the cell openings COP includes a wet etching process of patterning the substrate 1800 including (or containing) silicon (Si) and the first inorganic film 1910 including (or containing) silicon oxide (SiOₓ).

According to one embodiment, the deposition thickness of the third inorganic film 1930 on the side surface of the second inorganic film pattern 1921 increases as it approaches the top surface of the second inorganic film pattern 1921. For example, the deposition thickness of the third inorganic film 1930 may increase in the third direction DR3 in which the top surface of the second inorganic film pattern 1921 faces. Accordingly, the cross-sectional structure of the mask membrane MM including the second inorganic film pattern 1921 and the third inorganic film 1930 deposited thereon has a reverse tapered shape.

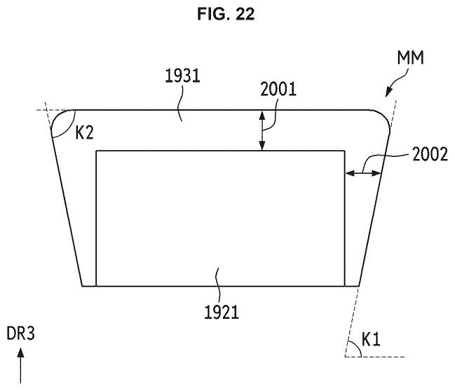

FIG. 22 is a cross-sectional view of a mask membrane according to one embodiment. For example, FIG. 22 illustrates a cross-sectional structure of one mask membrane.

Referring to FIG. 22, the cross-sectional structure of the mask membrane MM includes the second inorganic film pattern 1921 and the third inorganic film 1930 (e.g., the third inorganic film pattern 1931) covering the top and side surfaces of the second inorganic film pattern 1921.

According to one embodiment, the deposition thickness of the third inorganic film 1930 (e.g., the third inorganic film pattern 1931) on the side surface of the second inorganic film pattern 1921 increases as it approaches the top surface of the second inorganic film pattern 1921. For example, the deposition thickness of the third inorganic film 1930 (e.g., the third inorganic film pattern 1931) may increase in the third direction DR3 in which the top surface of the second inorganic film pattern 1921 faces. Accordingly, the cross-sectional structure of the mask membrane MM including the second inorganic film pattern 1921 and the third inorganic film 1930 (e.g., the third inorganic film pattern 1931) deposited thereon has a reverse tapered shape.

According to one embodiment, the deposition thickness of the third inorganic film 1930 (e.g., the third inorganic film pattern 1931) on the side surface of the second inorganic film pattern 1921 may be less than the deposition thickness of the third inorganic film 1930 (e.g., the third inorganic film pattern 1931) on the top surface of the second inorganic film pattern 1921.

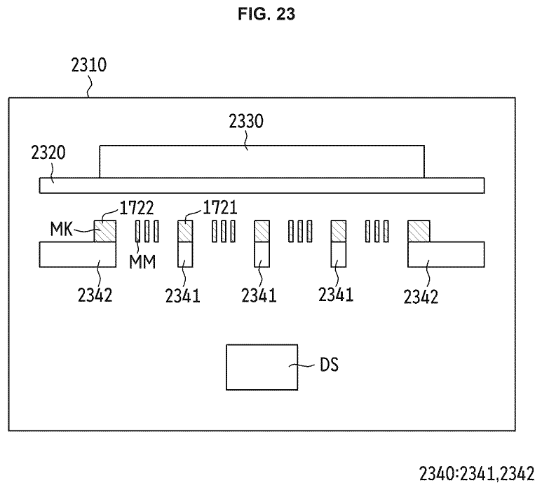

According to one embodiment, assuming a deposition angle K1 from a deposition source DS (see, e.g., FIG. 23) relative to the mask membrane MM is about 70 degrees, a taper angle K2 of the mask membrane MM may be in a range of about 70 degrees to about 90 degrees.

According to one embodiment, the deposition thickness of the third inorganic film 1930 on the side surface of the second inorganic film pattern 1921 may be less than about 0.4 μm, and the deposition thickness of the third inorganic film 1930 on the top surface of the second inorganic film pattern 1921 may be less than about 1 μm.

FIG. 23 is a configuration diagram schematically illustrating deposition equipment according to one embodiment.

Referring to FIG. 23, the deposition equipment, according to one embodiment, includes a chamber 2310, the deposition source DS disposed inside the chamber 2310, the mask MK disposed between a first substrate 2320 and the deposition source DS inside the chamber 2310, and a mask support 2340 disposed between the deposition source DS and the mask MK to support at least a portion of the mask MK.

According to one embodiment, the mask MK includes a second substrate 1700 (see, e.g., FIG. 12) including the plurality of cell regions 1710 and the mask frame region 1720 excluding the plurality of cell regions 1710, and the mask membrane MM disposed in each cell region 1710.

The first substrate 2320, as shown in FIG. 23, may be the display panel 100 described with reference to FIGS. 1 to 10. Therefore, the description of the first substrate 2320 may be replaced with the description of the display panel 100 with reference to FIGS. 1 to 10 and is not repeated.

The second substrate 1700, as shown in FIG. 23, may be the silicon substrate 1700 described with reference to FIGS. 13 to 22. Therefore, the description of the second substrate 1700 may be replaced with the description of the silicon substrate 1700 with reference to FIGS. 13 to 22 and is not repeated.

The mask support 2340 may support and fix the mask MK from under the mask MK. For example, the mask support 2340 may include an electrostatic chuck. According to one embodiment, the mask support 2340 may include a first support region 2341 supporting the mask lip region 1721 and a second support region 2342 supporting the outer frame region 1722. However, the mask support 2340 may not support the mask lip region 1721, and for example, the first support region 2341 may be omitted.

The reference numeral 2330, as shown in FIG. 23, is a fixing member 2330 for securing the first substrate 2320, which may include, for example, an electrostatic chuck.

The display device according to one embodiment of the present disclosure can be applied to various electronic devices. The electronic device according to one embodiment of the present disclosure includes the display device described above and may further include modules or devices having additional functions in addition to the display device.

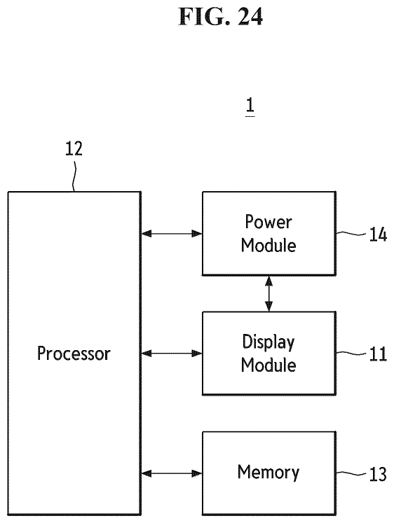

FIG. 24 is a block diagram of an electronic device according to one embodiment of the present disclosure.

Referring to FIG. 24, the electronic device 1 according to one embodiment of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 15 may store data information necessary for the operation of the processor 12 or the display module 11. When the processor 12 executes an application stored in the memory 15, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 1.

At least one of the components of the electronic device 11 according to the one embodiment of the present disclosure may be included in the display device 10 according to the embodiments of the present disclosure. In addition, some modules of the individual modules functionally included in one module may be included in the display device 10, and other modules may be provided separately from the display device 10. For example, the display device 10 may include the display module 11, and the processor 12, the memory 13, and the power module 14 may be provided in the form of other devices within the electronic device 11 other than the display device 10.

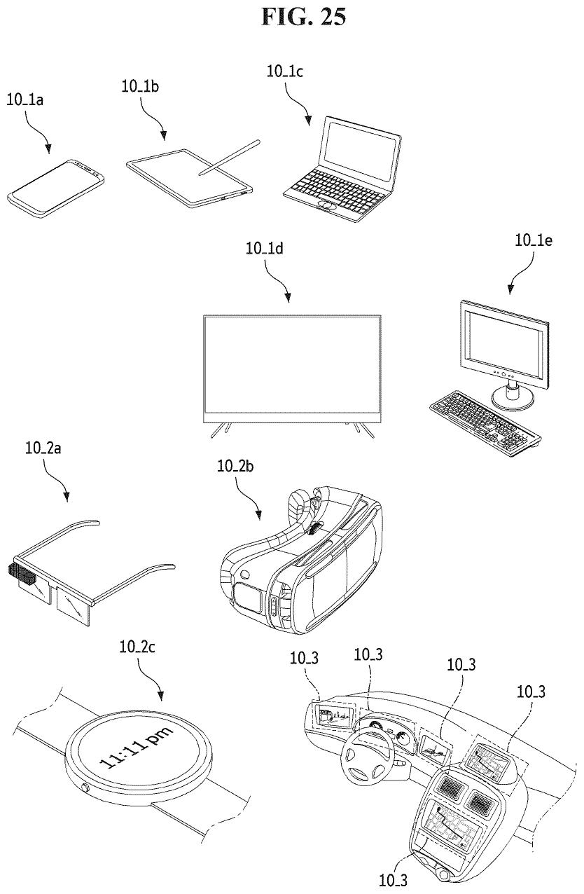

FIG. 25 is a schematic diagram of an electronic device according to various embodiments of the present disclosure.

Referring to FIG. 25, various electronic devices to which display devices 10 according to embodiments of the present disclosure are applied may include not only image display electronic devices such as a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and dashboard of an automobile.

In concluding the detailed description, those skilled in the art will appreciate that many variations and modifications can be made to the embodiments described herein without substantially departing from the spirit of the present disclosure. Therefore, the disclosed embodiments of the present disclosure are used in a generic and descriptive sense and not for purposes of limitation.

What is claimed is:

1. A deposition mask comprising:
a substrate;
a first inorganic film on the substrate; and
a mask membrane on the first inorganic film and comprising a second inorganic film and a third inorganic film,
wherein a cross-sectional structure of the mask membrane has a reverse tapered shape formed by a second inorganic film pattern obtained by patterning the second inorganic film and the third inorganic film covering a top surface and a side surface of the second inorganic film pattern.

2. The deposition mask of claim 1, wherein a thickness of the third inorganic film covering the side surface of the second inorganic film pattern in the mask membrane increases as it approaches the top surface of the second inorganic film pattern.

3. A method of manufacturing a deposition mask, the method comprising:
depositing a first inorganic film and a second inorganic film on a substrate;
forming a plurality of second inorganic film patterns corresponding to a cell region of the substrate by patterning the second inorganic film;
forming a cell opening exposing the second inorganic film pattern by etching the substrate and the first inorganic film from a lower direction of the substrate; and
depositing a third inorganic film covering a top surface and a side surface of the second inorganic film pattern,
wherein, in the depositing of the third inorganic film, the second inorganic film pattern and the third inorganic film deposited on a surface of the second inorganic film pattern form a mask membrane having a reverse tapered shape.

4. The method of claim 3, wherein the substrate comprises silicon.

5. The method of claim 3, wherein the first inorganic film comprises silicon oxide.

6. The method of claim 3, wherein the second inorganic film comprises silicon nitride.

7. The method of claim 3, wherein the third inorganic film is deposited by using a chemical vapor deposition method.

8. The method of claim 3, wherein the third inorganic film is deposited by using an atomic layer deposition method.

9. The method of claim 3, wherein a material of the third inorganic film is the same as a material of the first inorganic film or a material of the second inorganic film.

10. The method of claim 3, wherein a taper angle of the mask membrane is in a range of 70 degrees to 90 degrees.

11. The method of claim 3, wherein a deposition thickness of the third inorganic film on the side surface of the second inorganic film pattern is less than 0.4 μm, and
wherein a deposition thickness of the third inorganic film on the top surface of the second inorganic film pattern is less than 1 μm.

12. A method of manufacturing a deposition mask, the method comprising:
depositing a first inorganic film and a second inorganic film on a substrate;
forming a plurality of second inorganic film patterns corresponding to a cell region of the substrate by patterning the second inorganic film;
depositing a third inorganic film covering a top surface and a side surface of the second inorganic film pattern;
removing the third inorganic film deposited on the top surface of the second inorganic film pattern by polishing a top surface of the substrate on which the third inorganic film is deposited; and
forming a cell opening exposing the second inorganic film pattern by etching the substrate and the first inorganic film from a lower direction of the substrate,
wherein, in the depositing of the third inorganic film, the second inorganic film pattern and the third inorganic film deposited on a surface of the second inorganic film pattern form a mask membrane having a reverse tapered shape.

13. The method of claim 12, wherein the substrate comprises silicon.

14. The method of claim 12, wherein the first inorganic film comprises silicon oxide.

15. The method of claim 12, wherein the second inorganic film comprises silicon nitride.

16. The method of claim 12, wherein the third inorganic film is deposited by using a chemical vapor deposition method.

17. The method of claim 12, wherein the third inorganic film is deposited by using an atomic layer deposition method.

18. The method of claim 12, wherein a material of the third inorganic film is the same as a material of the first inorganic film or a material of the second inorganic film.

19. The method of claim 12, wherein a taper angle of the mask membrane is in a range of 70 degrees to 90 degrees.

20. The method of claim 12, wherein a deposition thickness of the third inorganic film on the side surface of the second inorganic film pattern is less than 0.4 μm, and
wherein a deposition thickness of the third inorganic film on the top surface of the second inorganic film pattern is less than 1 μm.

21. An electronic device comprising:
a display device manufactured using a deposition mask and configured to provide an image;
a processor configured to provide an image data signal to the display device;
a memory configured to store a data information for operation; and
a power module configured to generate power,
wherein the deposition mask comprises:
a substrate;
a first inorganic film on the substrate; and
a mask membrane on the first inorganic film and comprising a second inorganic film and a third inorganic film,
wherein a cross-sectional structure of the mask membrane has a reverse tapered shape formed by a second inorganic film pattern obtained by patterning the second inorganic film and the third inorganic film covering a top surface and a side surface of the second inorganic film pattern.
